(19) United States
(12) Patent Application Publication
(10) Pub. No.: US 2026/0371821 A1
(43) Pub. Date: Nov. 19, 2026

(54) OPTICAL DEVICE, DISPLAY DEVICE INCLUDING THE OPTICAL DEVICE, AND ELECTRONIC DEVICE INCLUDING THE DISPLAY DEVICE

(71) Applicant: Samsung Display Co., Ltd., Yongin-si (KR)

(72) Inventors: Jong Cheon LEE, Yongin-si (KR); Hae Ju YUN, Yongin-si (KR); Dong Chul SHIN, Yongin-si (KR); Ji Young NAM, Yongin-si (KR); Yong Seok KIM, Yongin-si (KR); Soo Bin KIM, Yongin-si (KR)

(21) Appl. No.: 19/456,332

(22) Filed: Jan. 22, 2026

(30) Foreign Application Priority Data
May 13, 2025 (KR) 10-2025-0061956

(51) Int. Cl. H10H 29/855

(52) U.S. Cl. CPC H10H 29/855

(57) ABSTRACT

An optical device includes: a substrate; a first electrode and a second electrode on the substrate and spaced apart from each other; a first refractive layer on the substrate and including a first material having a first refractive index; a second refractive layer on the first refractive layer and including a second material having a second refractive index that is lower than the first refractive index; a third refractive layer on the second refractive layer and including the first material; and a fourth refractive layer on the third refractive layer and including the second material, wherein the first refractive index of the first material is configured to change in response to an electric field generated by voltages applied to the first electrode and the second electrode.

### CROSS-REFERENCE TO RELATED APPLICATION

The present application claims priority to and the benefit of Korean Patent Application No. 10-2025-0061956, filed on May 13, 2025, in the Korean Intellectual Property Office, the entire disclosure of which is incorporated herein by reference.

### BACKGROUND

### 1 Field

Aspects of some embodiments of the present disclosure relate to an optical device, a display device including the optical device, and an electronic device including the display device.

### 2. Description of the Related Art

With the advancement of the information-oriented society, various types of display devices for displaying information have been developed. For example, an augmented reality (AR) device is a display device that overlays a virtual image onto a real-world image seen by the user’s eyes. As another example, a stereoscopic display device is a display device that displays left-eye and right-eye images separately in order to provide a stereoscopic effect based on binocular disparity.

A stereoscopic display device generally includes a spatial light modulator for modulating the phase or amplitude of light. However, in a spatial light modulator that forms a waveguide is formed and applies an electric field, the large size of the waveguide may increase the overall size of the stereoscopic display device. Therefore, it may be desirable to miniaturize the spatial light modulator.

The above information disclosed in this Background section is only for enhancement of understanding of the background and therefore the information discussed in this Background section does not necessarily constitute prior art.

### SUMMARY

Aspects of some embodiments of the present disclosure include a miniaturized optical device that modulates the phase or amplitude of light.

Aspects of some embodiments of the present disclosure include a display device including a miniaturized optical device that modulates the phase or amplitude of light.

Aspects of some embodiments of the present disclosure include an electronic device including a display device including a miniaturized optical device that modulates the phase or amplitude of light.

The characteristics of embodiments according to the present disclosure are not limited to those mentioned above, and other characteristics not explicitly stated will be clearly understood by those skilled in the art based on the following description.

According to some embodiments of the present disclosure, an optical device comprises a substrate, a first electrode and a second electrode positioned on the substrate and spaced apart from each other, a first refractive layer positioned on the substrate and including a first material having a first refractive index, a second refractive layer positioned on the first refractive layer and including a second material having a second refractive index that is lower than the first refractive index, a third refractive layer positioned on the second refractive layer and including the first material, and a fourth refractive layer positioned on the third refractive layer and including the second material, wherein the first refractive index of the first material

changes in response to an electric field generated by voltages applied to the first electrode and the second electrode.

According to some embodiments, a thickness of the third refractive layer is equal to a thickness of the first refractive layer.

According to some embodiments, a thickness of the fourth refractive layer is equal to a thickness of the second refractive layer.

According to some embodiments, a thickness of the second refractive layer is greater than a thickness of the first refractive layer.

According to some embodiments, the first electrode is positioned between the substrate and the first refractive layer, and the second electrode is positioned on the fourth refractive layer.

According to some embodiments, the first electrode is positioned on one side of the substrate and contacts the first through fourth refractive layers, and the second electrode is positioned on the other side of the substrate and contacts the first through fourth refractive layers.

According to some embodiments, a difference between the first and second refractive indices is equal to or greater than 0.5 and equal to or less than 1.5.

According to some embodiments, a difference between a maximum value and a minimum value of the first refractive index is equal to or greater than 0.01 and equal to or less than 0.03.

According to some embodiments of the present disclosure, a display device comprises a light source, and an optical device positioned on one side of the light source, wherein the optical device includes: a substrate; a first electrode and a second electrode positioned on the substrate and spaced apart from each other; a first refractive layer positioned on the substrate and including a first material having a first refractive index; a second refractive layer positioned on the first refractive layer and

including a second material having a second refractive index that is lower than the first refractive index; a third refractive layer positioned on the second refractive layer and including the first material; and a fourth refractive layer positioned on the third refractive layer and including the second material, and the first refractive index of the first material changes in response to an electric field generated by voltages applied to the first electrode and the second electrode.

According to some embodiments, the light source emits light in a predetermined wavelength band.

According to some embodiments, the display device further comprises an optical device driving unit configured to apply a first driving voltage and a second driving voltage to the first electrode and the second electrode, respectively.

According to some embodiments, the optical device reflects light emitted from the light source and modulates an amplitude of the light.

According to some embodiments, the optical device reflects light emitted from the light source as the electric field increases.

According to some embodiments, the optical device reflects light emitted from the light source as the electric field decreases.

According to some embodiments, the optical device transmits light emitted from the light source and modulates an amplitude of the light.

According to some embodiments, the optical device transmits light emitted from the light source as the electric field increases.

According to some embodiments of the present disclosure, an electronic device comprises a display module configured to display an image, and a processor configured to provide an image data signal for displaying the image to the display module, wherein the display module includes: a light source; and an optical device positioned on one side of the light source, the optical device includes: a substrate; a

first electrode and a second electrode positioned on the substrate and spaced apart from each other; a first refractive layer positioned on the substrate and including a first material having a first refractive index; a second refractive layer positioned on the first refractive layer and including a second material having a second refractive index that is lower than the first refractive index; a third refractive layer positioned on the second refractive layer and including the first material; and a fourth refractive layer positioned on the third refractive layer and including the second material, and the first refractive index of the first material changes in response to an electric field generated by voltages applied to the first and second electrodes.

According to some embodiments, the display module further includes an optical device driver configured to apply first and second driving voltages to the first and second electrodes, respectively.

According to some embodiments, the processor controls magnitudes and timings of the first and second driving voltages applied by the optical device driver to the first and second electrodes.

According to some embodiments, the electronic device is a mobile phone, smartphone, tablet personal computer (PC), mobile communication terminal, electronic notebook, electronic book (e-book) reader, portable multimedia player (PMP), navigation device, ultra mobile PC (UMPC), Internet of Things (IoT) device, television, laptop computer, monitor, signage display, smartwatch, watch phone, glasses-type display, head-mounted display, automotive instrument panel, automotive center fascia, automotive center information display (CID), or automotive room mirror display.

In an optical device, display device, and electronic device according to some embodiments of the present disclosure, the reflectance of the optical device may change upon application of an electric field for light of a wavelength that becomes null in the reflectance spectrum, thereby enabling amplitude modulation of incident light.

In an optical device, display device, and electronic device according to some embodiments of the present disclosure, the transmittance of the optical device may change upon application of an electric field for light of a wavelength that becomes null in the transmittance spectrum, thereby enabling amplitude modulation of incident light.

The optical device according to some embodiments of the present disclosure may modulate amplitude using a refractive layer having a thickness of several nanometers, thereby enabling the provision of an amplitude modulator with relatively reduced thickness compared to a conventional spatial light modulator.

It should be noted that the characteristics of embodiments according to the present disclosure are not limited to those described above, and other characteristics of embodiments according to the present disclosure will be apparent from the following description.

### BRIEF DESCRIPTION OF THE DRAWINGS

The above and other aspects and features of embodiments according to the present disclosure will become more apparent by describing in more details aspects of embodiments thereof in more detail with reference to the attached drawings, in which:

FIG. 1 is a block diagram of a display device including an optical device according to some embodiments of the present disclosure.

FIG. 2 is a side view of an optical device according to some embodiments of the present disclosure.

FIG. 3 is a side view of an optical device according to some embodiments of the present disclosure.

FIG. 4 is a side view of an optical device according to some embodiments of the present disclosure.

FIG. 5 is a plan view of the optical device of FIG. 4.

FIG. 6 is a graph showing reflectance according to electric field in the optical devices of FIGS. 2 through 4.

FIG. 7 illustrates wavelength-specific reflectance spectra, under different electric fields, of the optical device according to some embodiments.

FIG. 8 is an enlarged graph illustrating an example of region A in FIG. 7.

FIG. 9 is an enlarged graph illustrating another example of region A in FIG. 7.

FIG. 10 is a graph showing wavelength-specific transmittance of the optical device according to some embodiments of the present disclosure.

FIG. 11 is an enlarged graph illustrating an example of region B in FIG. 10.

FIG. 12 is a block diagram of an electronic device according to some embodiments of the present disclosure.

FIG. 13 illustrates schematic diagrams of electronic devices according to various embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

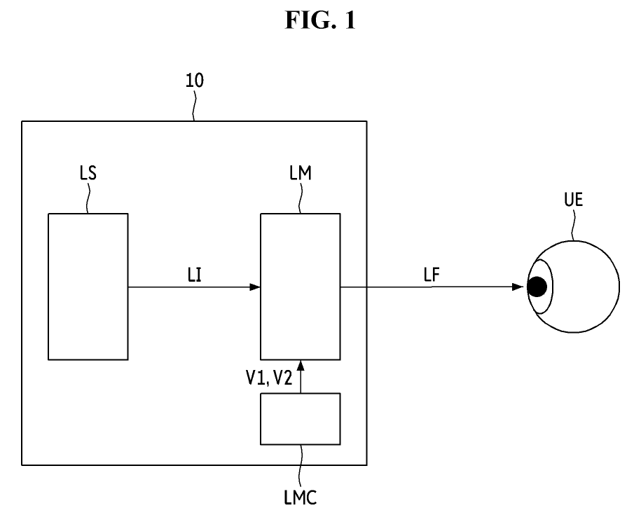

FIG. 1 is a block diagram of a display device including an optical device according to some embodiments of the present disclosure.

Referring to FIG. 1, a display device 10 may include a light source LS, an optical device LM, and an optical device driver LMC.

The display device 10 may be a display device such as an organic light-emitting display device using organic light-emitting diodes, a quantum dot light-emitting display device including a quantum dot light-emitting layer, an inorganic light-emitting display device including an inorganic semiconductor, a micro light-emitting display device using micro or nano light-emitting diodes (micro LEDs or nano LEDs), an electrochromic display device using a redox reaction, or a display device including a narrowband light source such as a laser. For convenience, the display device 10 will hereinafter be described as being a display device including a narrowband light source, but the present disclosure is not limited thereto.

The light source LS may emit initial light LI. The initial light LI may be light in a wavelength band (e.g., a set or predetermined wavelength band). For example, the light source LS may be a device that emits light in a wavelength band (e.g., a set or predetermined wavelength band), such as a laser.

The optical device LM may receive the initial light LI from the light source LS. The optical device LM may modulate the amplitude or phase of the initial light LI. The optical device LM may provide final light LF, in which the amplitude or phase of the initial light LI is modulated, to a user UE. For convenience, the optical device LM will hereinafter be described as modulating the amplitude of the initial light LI.

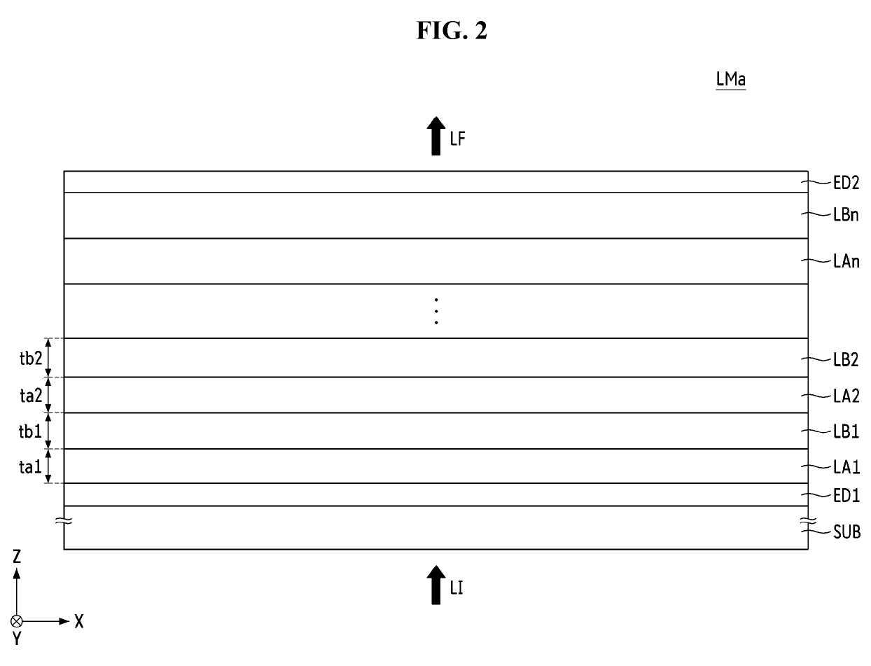

The optical device driver LMC may deliver drive signals to the optical device LM. The optical device driver LMC may deliver a first drive signal V1 and a second drive signal V2 to the optical device LM. The first drive signal V1 may include the magnitude and timing of a first drive voltage applied to a first electrode ED1 in FIG. 2. The second drive signal V2 may include the magnitude and timing of a second drive voltage applied to a second electrode ED2 in FIG. 2. According to the drive signals delivered by the optical device driver LMC, drive voltages may be applied to the optical device LM.

The display device 10 may be applied to a portable electronic device such as a mobile phone, a smart phone, a tablet personal computer (tablet PC), a mobile communication terminal, an electronic notepad, an electronic book reader, a portable multimedia player (PMP), a navigation device, or an ultra mobile PC (UMPC). Alternatively, the display device 10 may be applied as a display unit of a television, a laptop computer, a monitor, an advertisement board, or an Internet of Things (IoT) device. Yet alternatively, the display device 10 may be applied to a wearable device

such as a smart watch, a watch phone, a glasses-type display, or a head mounted display (HMD). Still alternatively, the display device 10 may be applied to a display mounted in a vehicle, such as an instrument panel, a center fascia of a vehicle, a Center Information Display (CID) on a dashboard of a vehicle, a room mirror display replacing a side mirror, or a display for rear-seat entertainment on the rear surface of a front seat.

FIG. 2 is a side view of an optical device according to some embodiments of the present disclosure.

Referring to FIG. 2, an optical device LMa according to some embodiments may include a substrate SUB, a first electrode ED1, first, second, third, fourth, …, (2n-1)-th, and 2n-th refractive layers LA1, LB1, LA2, LB2, …, LAn, and LBn, and a second electrode ED2.

In FIG. 2, the initial light LI incident on the optical device LMa may travel in a third direction, and the final light LF emitted from the optical device LMa may also travel in the third direction.

The substrate SUB may transmit the initial light LI emitted from the light source LS. The substrate SUB may include a transparent material such as quartz or plastic. For example, the substrate SUB may extend in a first direction (e.g., an X-axis direction) and a second direction (e.g., a Y-axis direction).

The first electrode ED1 may be positioned on the substrate SUB. The first electrode ED1 may extend in a direction parallel to the substrate SUB. For example, the first electrode ED1 may extend in the first and second directions. The first electrode ED1 may overlap the substrate SUB in the third direction.

The first electrode ED1 may transmit the initial light LI. The first electrode ED1 may be a transparent electrode capable of transmitting light therethrough. For example, the first electrode ED1 may be formed using a transparent conductive oxide (TCO), such as ITO or IZO, which can transmit light, or a semi-transmissive conductive material, such as magnesium (Mg), silver (Ag), or an alloy thereof.

A first refractive layer LA1 may be positioned on the first electrode ED1. The first refractive layer LA1 may extend in a direction parallel to the first electrode ED1. For example, the first refractive layer LA1 may extend in the first and second directions. The first refractive layer LA1 may overlap the substrate SUB and the first electrode ED1 in the third direction.

The first refractive layer LA1 may include a first material having a first refractive index. The first refractive index of the first material may vary in response to an electric field generated by the voltages applied to the first and second electrodes ED2. A difference between the maximum value and minimum value of the first refractive index may be equal to or greater than 0.01 and equal to or less than 0.03. For example, the first material may include lithium niobate (LiNbO₃), in which case, the first refractive index may vary within a range of 2.19 to 2.23 (or approximately 2.19 to 2.23) depending on the electric field. However, the first material is not limited to LiNbO₃ and may include other materials whose refractive index varies in response to an electric field, such as barium titanate (BaTiO₃) or monopotassium phosphate (KH₂PO₄).

In some embodiments, the first material may include a material whose first refractive index varies depending on the ambient temperature of the optical device LM, such as germanium antimony telluride (GeSbTe). For convenience, the first refractive index will hereinafter be described as varying depending on an electric field.

A first thickness ta1 of the first refractive layer LA1 may be proportional to a design center wavelength and inversely proportional to the first refractive index. For example, a first thickness ta1 for red initial light LI may be greater than a first thickness ta1 for green initial light LI. A first thickness ta1 for a first material with a relatively high first refractive index may be smaller than a first thickness ta1 for a first material with a relatively low first refractive index.

A second refractive layer LB1 may be positioned on the first refractive layer LA1. The second refractive layer LB1 may extend in a direction parallel to the first refractive layer LA1. For example, the second refractive layer LB1 may extend in the first and second directions. The second refractive layer LB1 may overlap the substrate SUB, the first electrode ED1, and the first refractive layer LA1 in the third direction.

The second refractive layer LB1 may include a second material having a second refractive index. The second refractive index of the second material may have a constant value regardless of the electric field generated by the voltages applied to the first and second electrodes ED1 and ED2. For example, the second material may include silicon dioxide (SiO₂), in which case, the second refractive index may have a constant value in the range of 1.4 to 1.6 (or approximately 1.4 to 1.6). However, the second material is not limited to SiO₂ and may include other materials whose refractive index remains constant even when an electric field is applied.

The second refractive index may be greater or less than the first refractive index. A difference between the first and second refractive indices may be equal to or greater than 0.5 and equal to or less than 1.5. Additionally, instead of the first refractive layer LA1 including a first material with a variable refractive index depending on an electric field, the second refractive layer LB1 including a second material with a fixed second refractive index may be stacked first on the substrate SUB. For convenience, the first refractive index will hereinafter be described as being greater than the second refractive index, and the first refractive layer LA1 as being stacked on the substrate SUB ahead of the second refractive layer LB1.

A second thickness tb1 of the second refractive layer LB1 may be proportional to the design center wavelength and inversely proportional to the second refractive index. For example, a second thickness tb1 for red initial light LI may be greater than a second thickness tb1 for green initial light LI. A second thickness tb1 for a second material with a relatively high second refractive index may be smaller than a second thickness tb1 for a second material with a relatively low second refractive index.

The second thickness tb1 of the second refractive layer LB1 may be greater than the first thickness ta1 of the first refractive layer LA1 because the second refractive index of the second material included in the second refractive layer LB1 is smaller than the first refractive index of the first material included in the first refractive layer LA1.

A third refractive layer LA2 may be positioned on the second refractive layer LB1. The third refractive layer LA2 may extend in a direction parallel to the second refractive layer LB1. For example, the third refractive layer LA2 may extend in the first and second directions. The third refractive layer LA2 may overlap the substrate SUB, the first electrode ED1, the first refractive layer LA1, and the second refractive layer LB1 in the third direction.

The third refractive layer LA2 may include the first material having the first refractive index. The third refractive layer LA2 may be substantially the same as the first refractive layer LA1. Similarly to what has been described above with the first refractive layer LA1, the first refractive index of the first material included in the third refractive layer LA2 may vary depending on the electric field generated by the voltages applied to the first and second electrodes ED1 and ED2. A third thickness ta2 of the third refractive layer LA2 may be equal to the first thickness ta1 of the first refractive layer LA1.

A fourth refractive layer LB2 may be positioned on the third refractive layer LA2. The fourth refractive layer LB2 may extend in a direction parallel to the third refractive layer LA2. For example, the fourth refractive layer LB2 may extend in the first and second directions. The fourth refractive layer LB2 may overlap the substrate SUB, the first electrode ED1, the first refractive layer LA1, the second refractive layer LB2, and the third refractive layer LA3 in the third direction.

The fourth refractive layer LB2 may include the second material having the second refractive index. The second refractive index of the second material may have a constant value regardless of the electric field generated by the voltages applied to the first and second electrodes ED1 and ED2. The fourth refractive layer LB2 may be substantially the same as the second refractive layer LB1. A fourth thickness tb2 of the fourth refractive layer LB2 may be equal to the second thickness tb1 of the second refractive layer LB1.

A fifth refractive layer including the first material and a sixth refractive layer including the second material may be alternately positioned on the fourth refractive layer LB2. On the substrate SUB, n refractive layers including the first material may be arranged, and n refractive layers including the second material may be arranged (where n is a natural number equal to or greater than 2). The (2n−1)-th refractive layer LAn may include the first material and may be substantially the same as the first refractive layer LA1. The thickness of the (2n−1)-th refractive layer LAn may be equal to the first thickness ta1. The 2n-th refractive layer LBn may include the second material and may be substantially the same as the second refractive layer LB1. The thickness of the 2n-th refractive layer LBn may be equal to the second thickness tb1.

The second electrode ED2 may be positioned on the 2n-th refractive layer LBn. The second electrode ED2 may be a transparent electrode capable of transmitting light therethrough. The second electrode ED2 may be substantially the same as the first electrode ED1.

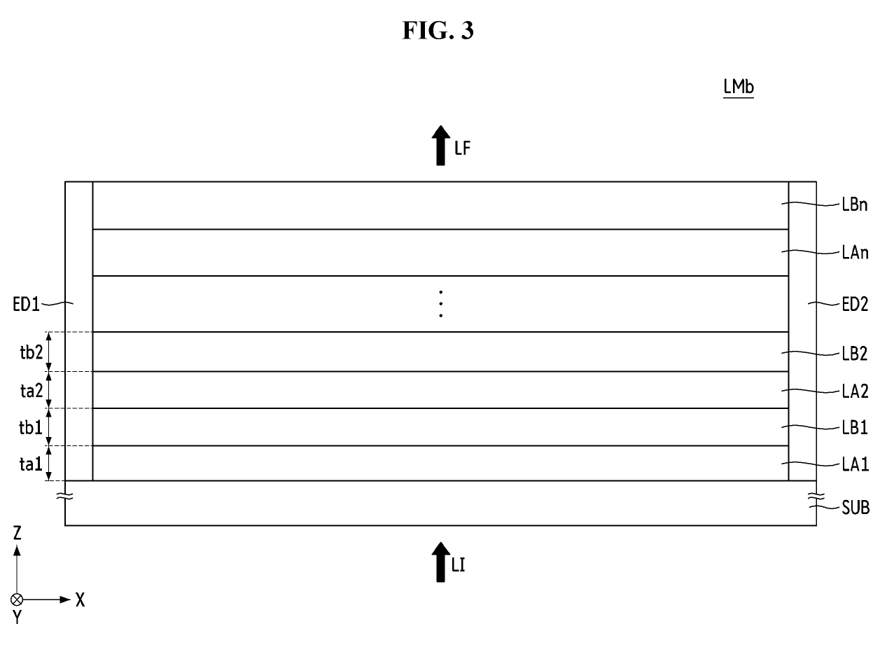

FIG. 3 is a side view of an optical device according to some embodiments of the present disclosure. In the following description, any redundant descriptions will be omitted, and differences will be primarily described.

Referring to FIG. 3, initial light LI incident on an optical device LMb may travel in a third direction (e.g., a Z-axis direction), and final light LF emitted from the optical device LMb may also travel in the third direction.

As illustrated in FIG. 3, the optical device LMb may include a substrate SUB, a first electrode ED1, first, second, third, fourth, …, (2n-1)-th, and 2n-th refractive layers LA1, LB1, LA2, LB2, …, LAn, and LBn, and a second electrode ED2.

The substrate SUB may extend in a first direction (e.g., an X-axis direction) and a second direction (e.g., a Y-axis direction).

The first electrode ED1 may be positioned on one side of the substrate SUB. The first electrode ED1 may extend in a direction intersecting the substrate SUB. For example, the first electrode ED1 may extend in the second and third directions. One edge of the first electrode ED1 may be aligned with one edge of the substrate SUB in the third direction.

The second electrode ED2 may be positioned on the other side of the substrate SUB. The second electrode ED2 may extend in a direction intersecting the substrate SUB. The second electrode ED2 may face the first electrode ED1. For example, the second electrode ED2 may extend in the second and third directions. One edge of the second electrode ED2 may be aligned with the other edge of the substrate SUB in the third direction.

The first, second, third, fourth, …, (2n-1)-th, and 2n-th refractive layers LA1, LB1, LA2, LB2, …, LAn, and LBn may be positioned between the first and second electrodes ED1 and ED2. One side of each of the first, second, third, fourth, …, (2n-1)-th, and 2n-th refractive layers LA1, LB1, LA2, LB2, …, LAn, and LBn may contact the first electrode ED1. The other side of each of the first, second, third, fourth, …, (2n-1)-th, and 2n-th refractive layers LA1, LB1, LA2, LB2, …, LAn, and LBn may contact the second electrode ED2.

The upper surface of the substrate SUB may contact the lower surface of the first electrode ED1, the lower surface of the first refractive layer LA1, and the lower surface of the second electrode ED2.

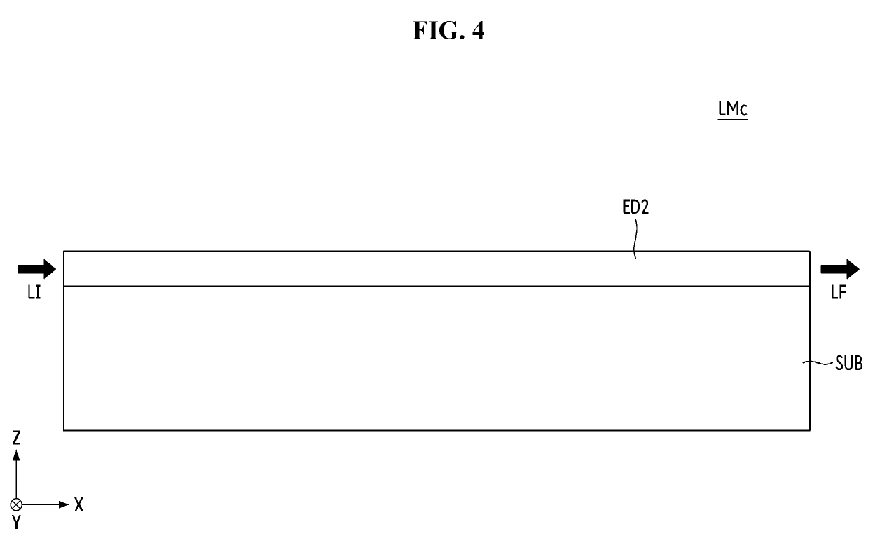

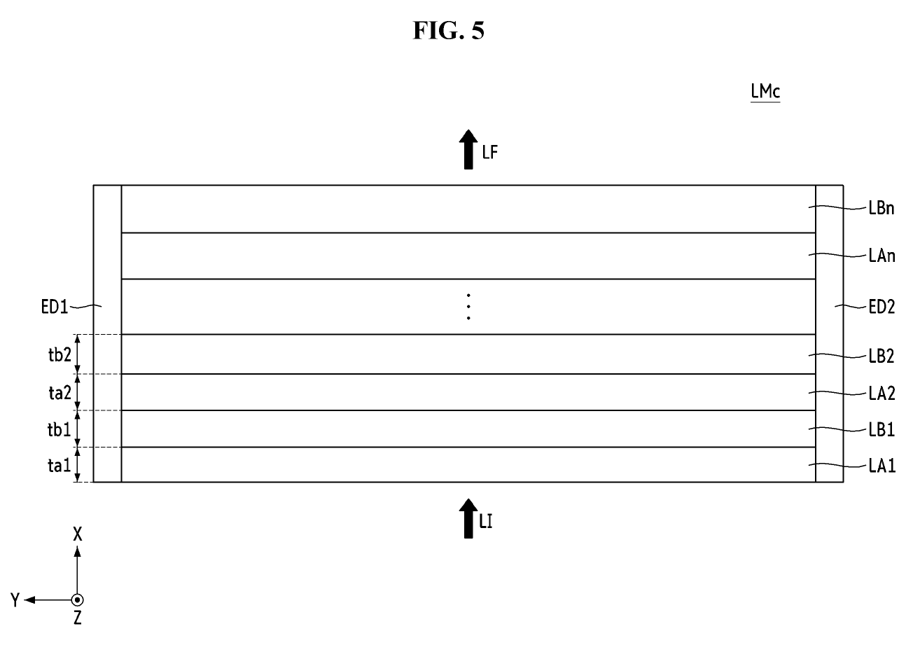

FIG. 4 is a side view of an optical device according to some embodiments of the present disclosure. FIG. 5 is a plan view of the optical device of FIG. 4. In the following description, any redundant descriptions will be omitted, and differences will be primarily described.

Referring to FIGS. 4 and 5, initial light LI incident on an optical device LMc may travel in a first direction (e.g., an X-axis direction), and final light LF emitted from the optical device LMc may also travel in the first direction.

As illustrated in FIG. 4, the optical device LMc may include a substrate SUB and a second electrode ED2.

The substrate SUB may extend in a first direction (e.g., an X-axis direction) and a second direction (e.g., a Y-axis direction).

The second electrode ED2 may be positioned on one side of the substrate SUB. The lower surface of the second electrode ED2 may contact the upper surface of the substrate SUB. The second electrode ED2 may extend in a direction parallel to the substrate SUB. For example, the second electrode ED2 may extend in the first direction. The second electrode ED2 may overlap a portion of the substrate SUB in a third direction (e.g., a Z-axis direction).

Referring to FIG. 5, a first electrode ED1, the second electrode ED2, and first, second, third, fourth, …, (2n-1)-th, and 2n-th refractive layers LA1, LB1, LA2, LB2, …, LAn, and LBn may be positioned on the substrate SUB.

The first electrode ED1 may be positioned on the other side of the substrate SUB. For example, the first electrode ED1 may extend in the first direction. In FIG. 5, the left edge of the first electrode ED1 is illustrated as covering the left edge of the substrate SUB, but the present disclosure is not limited thereto. The left edge of the substrate SUB may protrude in the second direction beyond the left edge of the first electrode ED1.

The second electrode ED2 may be positioned on one side of the substrate SUB. The second electrode ED2 may face the first electrode ED1. For example, the second electrode ED2 may extend in the first direction. In FIG. 5, the right edge of the second electrode ED2 is illustrated as covering the right edge of the substrate SUB, but the present disclosure is not limited thereto. The right edge of the substrate SUB may protrude in a direction opposite to the second direction beyond the right edge of the second electrode ED2.

The first, second, third, fourth, …, (2n-1)-th, and 2n-th refractive layers LA1, LB1, LA2, LB2, …, LAn, and LBn may be positioned between the first and second electrodes ED1 and ED2. The left side of each of the first, second, third, fourth, …, (2n-1)-th, and 2n-th refractive layers LA1, LB1, LA2, LB2, …, LAn, and LBn may contact the first electrode ED1. The right side of each of the first, second, third, fourth, …, (2n-1)-th, and 2n-th refractive layers LA1, LB1, LA2, LB2, …, LAn, and LBn may contact the second electrode ED2.

The upper surface of the substrate SUB may contact the lower surface of the first electrode ED1, the lower surface of the second electrode ED2, and the lower surfaces of the first, second, third, fourth, …, (2n-1)-th, and 2n-th refractive layers LA1, LB1, LA2, LB2, …, LAn, and LBn.

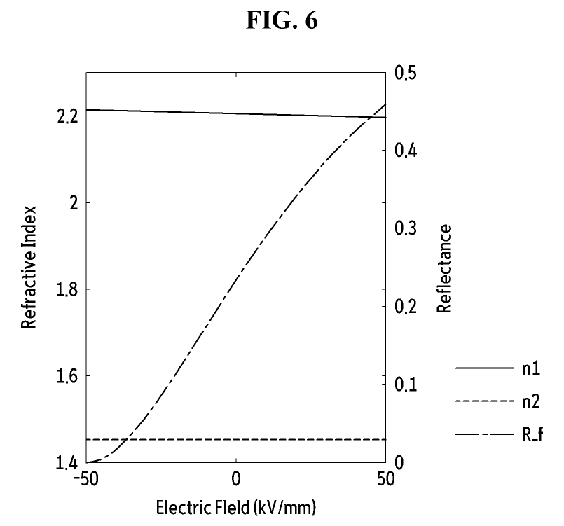

FIG. 6 is a graph showing reflectance according to electric field in the optical devices of FIGS. 2 through 4.

FIG. 6 illustrates an example of the variation of a first refractive index n1 of a first refractive layer LA1 including lithium niobate, a second refractive index n2 of a second refractive layer LB1 including silicon dioxide, and a reflectance R_f of the optical device LM against electric field. The refractive indices and reflectances in FIG. 6 may be values for a wavelength band (e.g., a set or predetermined wavelength band).

Referring to FIG. 6, the first refractive index n1 may vary linearly in response to the electric field. For example, under an electric field of −50 kV/mm, the first refractive index n1 may be greater than 2.2. Under an electric field of 50 kV/mm, the first refractive index n1 may be less than 2.2. As the electric field generated by the voltages applied to the first and second electrodes ED1 and ED2 increases, the first refractive index n1 may decrease.

The second refractive index n2 may remain unchanged regardless of the electric field. For example, under an electric field of −50 kV/mm, the second refractive index n2 may be 1.45 (or approximately 1.45). Even under an electric field of 50 kV/mm, the second refractive index n2 may be 1.45 (or approximately 1.45). Even when the electric field generated by the voltages applied to the first and second electrodes ED1 and ED2 increases, the second refractive index n2 may remain constant.

The reflectance R_f of the optical device LM may increase in response to the electric field. For example, under an electric field of −50 kV/mm, the reflectance R_f may be 0 (or approximately 0). Under an electric field of 50 kV/mm, the reflectance R_f may be 0.46 (or approximately 0.46). As the electric field generated by the voltages applied to the first and second electrodes ED1 and ED2 increases, the reflectance R_f of the optical device LM may increase.

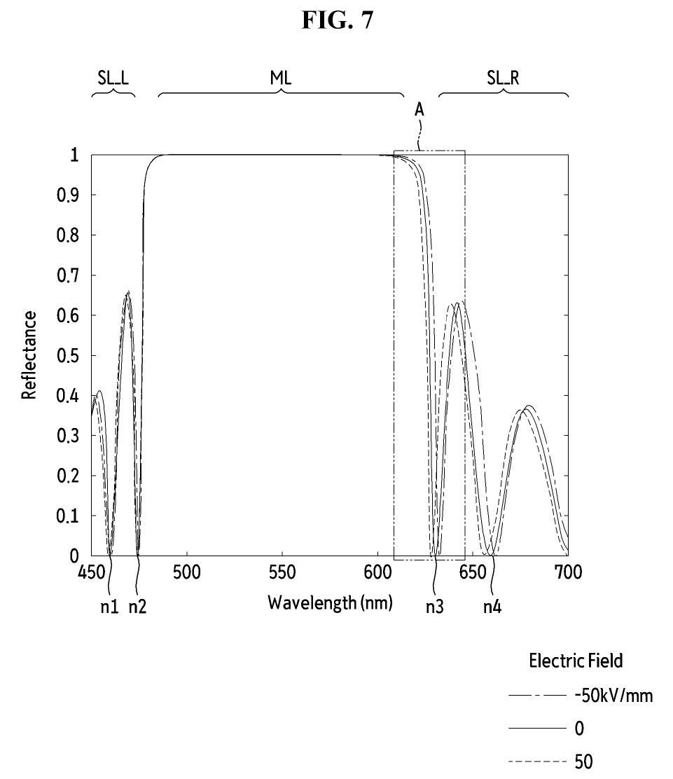

FIG. 7 is a graph showing wavelength-specific reflectance of the optical device according to some embodiments of the present disclosure.

FIG. 7 illustrates wavelength-specific reflectance spectra, under different electric fields, of the optical device according to some embodiments.

Referring to FIG. 7, the reflectance spectra may each include a main region ML, a left-side region SL_L, a right-side region SL_R, a first null n1, a second null n2, a third null n3, and a fourth null n4. Here, each null may indicate a point where the reflectance of the optical device LM is 0.

The main region ML may be a region where the reflectance of the optical device LM is 1, between adjacent nulls. For example, an average value of the wavelengths of the second and third nulls n2 and n3 adjacent to the main region ML may be defined as the design center wavelength of the optical device LM.

The design center wavelength may indicate which wavelength band of the light source LS the optical device LM operates on. For convenience, the optical device LM will hereinafter be described as operating on, for example, a visible light source LS.

The left-side region SL_L may be a region located to the left of the main region ML. In the left-side region SL_L, the reflectance of the optical device LM may have a plurality of maxima and minima. The plurality of maxima in the left-side region SL_L may decrease as the wavelength becomes shorter.

The plurality of minima in the left-side region SL_L may include the first and second nulls n1 and n2. The first and second nulls n1 and n2 may be wavelengths at which the reflectance of the optical device LM becomes 0. The first null n1 may be smaller than the second null n2. The second null n2 may serve as a reference for distinguishing the left-side region SL_L from the main region ML.

The right-side region SL_R may be a region located to the right of the main region ML. In the right-side region SL_R, the reflectance of the optical device LM may have a plurality of maxima and minima. The plurality of maxima in the right-side region SL_R may decrease as the wavelength becomes longer.

The plurality of minima in the right-side region SL_R may include the third and fourth nulls n3 and n4. The third and fourth nulls n3 and n4 may be wavelengths at which the reflectance of the optical device LM becomes 0. The third null n3 may be smaller than the fourth null n4. The third null n3 may serve as a reference for distinguishing the right-side region SL_R from the main region ML.

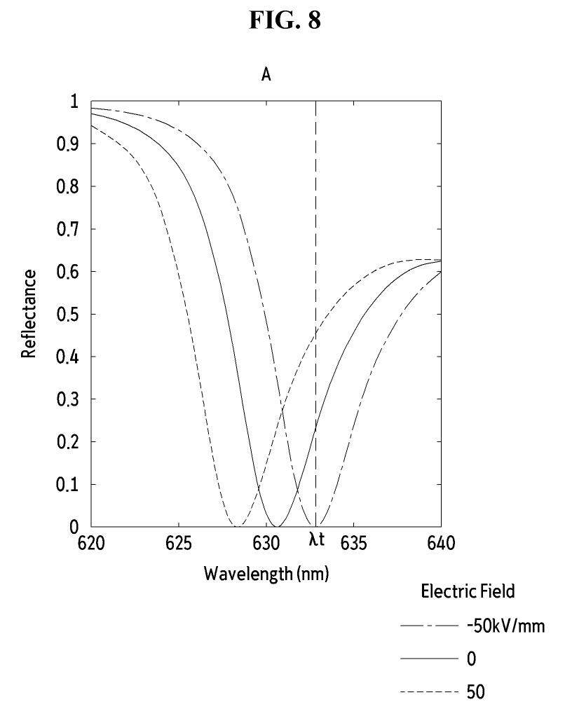

FIG. 8 is an enlarged graph illustrating an example of region A in FIG. 7.

Referring to FIG. 8, under an electric field of −50 kV/mm, the reflectance of the optical device LM at a target wavelength λt of 632 nanometers (nm) (or approximately 632 nm) may be 0. In other words, under an electric field of −50 kV/mm, the reflectance spectrum of the optical device LM may become null at the target wavelength λt.

Under an electric field of 0 kV/mm, the reflectance of the optical device LM at the target wavelength λt of 632 nanometers (nm) (or approximately 632 nm) may increase to 0.24 (or approximately 0.24).

Under an electric field of 5 kV/mm, the reflectance of the optical device LM at the target wavelength λt of 632 nanometers (nm) (or approximately 632 nm) may increase to 0.45 (or approximately 0.45).

In short, when using a light source LS having a wavelength of 632 nanometers (nm) (or approximately 632 nm), the reflectance of the optical device LM may increase as the electric field generated by the voltages applied to the first and second electrodes ED1 and ED2 increases. In particular, under an electric field of −50 kV/mm, the reflectance of the optical device LM may be 0. Accordingly, the optical device LM may operate as a reflective light modulator whose reflectance increases as the electric field increases. This may utilize changes in the reflectance of the optical device LM in response to electric field in the red wavelength band around the third null n3 in FIG. 7.

According to some embodiments, in the case of using changes in the reflectance of the optical device LM in response to electric field in the vicinity of the second null n2 in FIG. 7, the second null n2 may be 475 nm (or approximately 475 nm). In this case, the optical device LM may operate as a reflective light modulator for a blue light source LS.

According to some embodiments, the design center wavelength may be adjusted such that the third null n3 is relocated to 550 nm to 560 nm (or approximately 550 nm to 560 nm). In this case, the target wavelength λt may correspond to the relocated third null n3, and the optical device LM may operate as a reflective light modulator for a green light source LS.

The optical device LMa in FIG. 2, the optical device LMb in FIG. 3, and the optical device LMc of FIGS. 4 and 5 may all be used as reflective light modulators as described above with reference to FIG. 8. In this case, the optical device LM may modulate the amplitude of the final light LF in response to electric field.

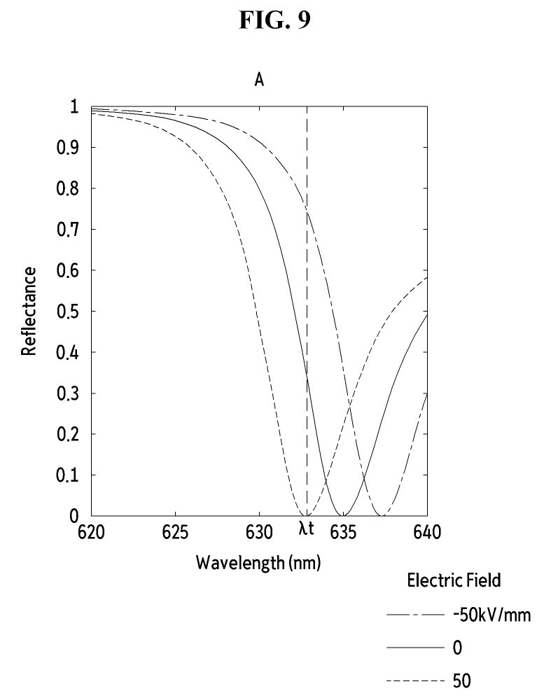

FIG. 9 is an enlarged graph illustrating further details of the region A in FIG. 7. In the following description, any redundant descriptions will be omitted, and differences will be primarily described.

FIG. 9 shows a reflectance spectrum having a longer design center wavelength than that of FIG. 8. As the design center wavelength of the optical device LM becomes longer, the third null n3, which distinguishes the main region ML from the right-side region SL_R, may also increase. Because the design center wavelength of the optical device LM is greater in the example of FIG. 9 than in the example of FIG. 8, the thickness of each refractive layer in the optical device LM may be greater in the example of FIG. 9 than in the example of FIG. 8. For example, the first thickness ta1 of the first refractive layer LA1 of the optical device LM may be greater in the example of FIG. 9 than in the example of FIG. 8. The second thickness tb1 of the second refractive layer LB1 of the optical device LM may also be greater in the example of FIG. 9 than in the example of FIG. 8.

Referring to FIG. 9, under an electric field of 50 kV/mm, the reflectance of the optical device LM at a target wavelength λt of 632 nm (or approximately 632 nm) may be 0. In other words, under an electric field of 50 kV/mm, the reflectance spectrum of the optical device LM may become null at the target wavelength λt.

Under an electric field of 0 kV/mm, the reflectance of the optical device LM at the target wavelength λt of 632 nm (or approximately 632 nm) may increase to 0.32 (or approximately 0.32).

Under an electric field of −50 kV/mm, the reflectance of the optical device LM at the target wavelength λt of 632 nm (or approximately 632 nm) may increase to 0.75 (or approximately 0.75).

In short, when using a light source LS having a wavelength of 632 nm (or approximately 632 nm), the reflectance of the optical device LM may increase as the electric field decreases. In particular, under an electric field of 50 kV/mm, the reflectance of the optical device LM may be 0. Accordingly, the optical device LM may operate as a reflective light modulator whose reflectance increases as the electric field decreases.

According to some embodiments, in the case of using changes in the reflectance of the optical device LM in response to electric field in the vicinity of the second null n2 in FIG. 7, the second null n2 may be 475 nm (or approximately 475 nm). In this case, the optical device LM may operate as a reflective light modulator for a blue light source LS.

According to some embodiments, the design center wavelength of the optical device LM may be adjusted such that the third null n3 is relocated to 550 nm to 560 nm (or approximately 550 nm to 560 nm). In this case, the target wavelength λt may correspond to the third null n3, and the optical device LM may operate as a reflective light modulator for a green light source LS.

The optical device LMa in FIG. 2, the optical device LMb in FIG. 3, and the optical device LMc in FIGS. 4 and 5 may all be used as reflective light modulators as described with reference to FIG. 9. In this case, the optical device LM may modulate the amplitude of the final light LF in response to electric field.

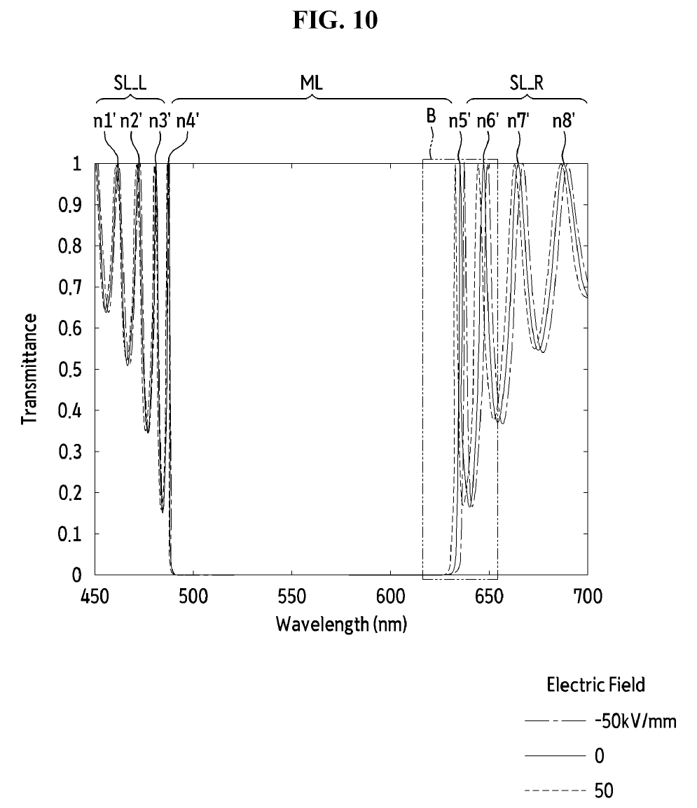

FIG. 10 is a graph showing wavelength-specific transmittance of the optical device according to some embodiments of the present disclosure.

Referring to FIG. 10, the transmittance spectrum may include a main region ML, a left-side region SL_L, a right-side region SL_R, and first through eighth nulls n1' through n8'. In the transmittance spectrum, each null may indicate a point where the transmittance of the optical device LM is 1.

The main region ML may be a region where the transmittance is 0, between adjacent nulls. For example, an average of the wavelengths of the fourth and fifth nulls n4' and n5' adjacent to the main region ML may be defined as the design center wavelength of the optical device LM.

The design center wavelength may indicate which wavelength band of a light source LS the optical device LM operates on. For convenience, the optical device LM will hereinafter be described as operating on, for example, a visible light source LS.

The left-side region SL_L may be a region located to the left of the main region ML. In the left-side region SL_L, the transmittance of the optical device LM may have a plurality of maxima and minima. The plurality of minima in the left-side region SL_L may increase as the wavelength becomes shorter.

The plurality of maxima in the left-side region SL_L may include the first through fourth nulls n1' through n4'. The first through fourth nulls n1' through n4' may be wavelengths at which the transmittance of the optical device LM becomes 1. The first null n1' may be smaller than the second null n2'. The second null n2' may be smaller than the third null n3'. The third null n3' may be smaller than the fourth null n4'. The fourth null n4' may serve as a reference for distinguishing the left-side region SL_L from the main region ML.

The right-side region SL_R may be a region located to the right of the main region ML. In the right-side region SL_R, the transmittance of the optical device LM may have a plurality of maxima and minima. The plurality of minima in the right-side region SL_R may increase as the wavelength becomes longer.

The plurality of maxima in the right-side region SL_R may include the fifth through eighth nulls n5' through n8'. The fifth through eighth nulls n5' through n8' may be wavelengths at which the transmittance of the optical device LM becomes 1. The fifth null n5' may be smaller than the sixth null n6'. The sixth null n6' may be smaller than the seventh null n7'. The seventh null n7' may be smaller than the eighth null n8'. The fifth null n5' may serve as a reference for distinguishing the right-side region SL_R from the main region ML.

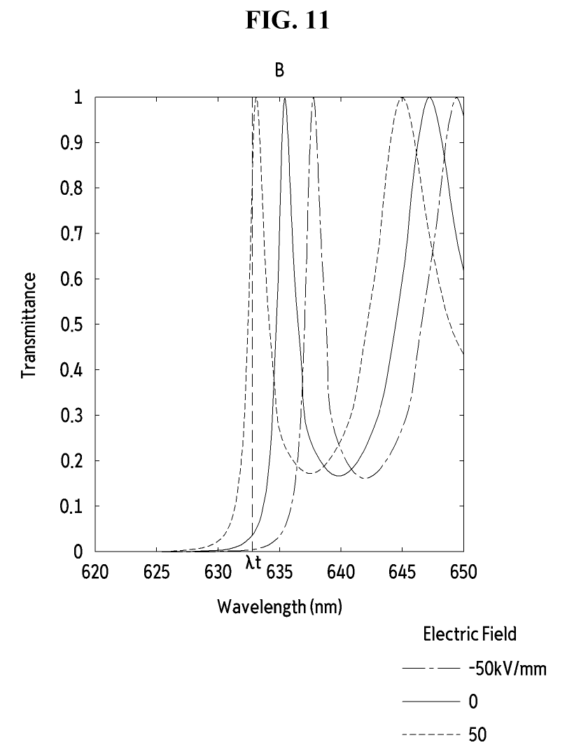

FIG. 11 is an enlarged graph illustrating an example of region B in FIG. 10.

Referring to FIG. 11, under an electric field of −50 kV/mm, the transmittance of the optical device LM at a target wavelength λt of 632 nm (or approximately 632 nm) may be 0.

Under an electric field of 0 kV/mm, the transmittance of the optical device LM at the target wavelength λt of 632 nm (or approximately 632 nm) may be approximately 0.03.

Under an electric field of 50 kV/mm, the transmittance of the optical device LM at the target wavelength λt of 632 nm (or approximately 632 nm) may be 1 (or approximately 1). In other words, under an electric field of 50 kV/mm, the transmittance spectrum of the optical device LM may become null at the target wavelength λt.

In short, when using a light source LS having a wavelength of 632 nm (or approximately 632 nm), the transmittance of the optical device LM may increase as the electric field generated by the voltages applied to the first electrode ED1 and the second electrode ED2 increases. In particular, under an electric field of 50 kV/mm, the transmittance of the optical device LM may be 1. Accordingly, the optical device LM may operate as a transmissive light modulator whose transmittance increases as the electric field increases.

According to some embodiments, in the case of using changes in the transmittance of the optical device LM in response to electric field in the vicinity of the fourth null n4' in FIG. 10, the fourth null n4' may be 480 nm (or approximately 480 nm). In this case, the optical device LM may operate as a transmissive light modulator for a blue light source LS.

According to some embodiments, the design center wavelength of the optical device LM may be adjusted such that the fifth null n5' is relocated to 550 nm to 560 nm (or approximately 550 nm to 560 nm). In this case, the target wavelength λt may correspond to the relocated fifth null n5', and the optical device LM may operate as a transmissive light modulator for a green light source LS.

The optical device LMa in FIG. 2, the optical device LMb in FIG. 3, and the optical device LMc in FIGS. 4 and 5 may all be used as transmissive light modulators as described with reference to FIG. 11. In this case, the optical device LM may modulate the amplitude of the final light LF in response to the electric field.

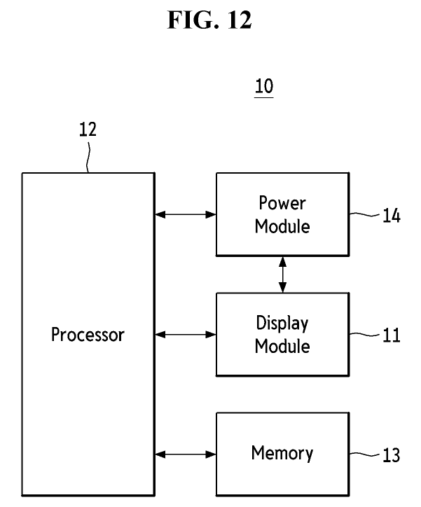

FIG. 12 is a block diagram of an electronic device according to some embodiments of the present disclosure.

Referring to FIG. 12, an electronic device 1 according to some embodiments may include a display module 11, a processor 13, a memory 12, and a power module 14.

The processor 13 may include at least one of a central processing unit (CPU), an application processor (AP), a graphics processing unit (GPU), a communication processor (CP), an image signal processor (ISP), or a controller.

The processor 13 may control the optical device driver LMC in FIG. 1. For example, the processor 13 may control the magnitudes and application timings of the first and second drive voltages applied by the optical device driver LMC to the optical device LM.

The memory 12 may store data and information required for the operation of the processor 13 or the display module 11. When the processor 13 executes an application stored in the memory 12, image data signals and/or input control signals may be delivered to the display module 11, and the display module 11 may process the received signals to output image information through a display screen.

The power module 14 may include a power supply module, such as a power adapter or a battery device, and a power conversion module that converts power supplied by the power supply module into power required for the operation of the electronic device 1.

At least one of the aforementioned components of the electronic device 1 may be included in a display device according to any one of the aforementioned embodiments. Additionally, some of individual modules included functionally within a single module may be included in the display device, and others may be provided separately from the display device. For example, the display device may include the display module 11, while the processor 13, the memory 12, and the power module 14 may be provided as other devices included in the electronic device 1.

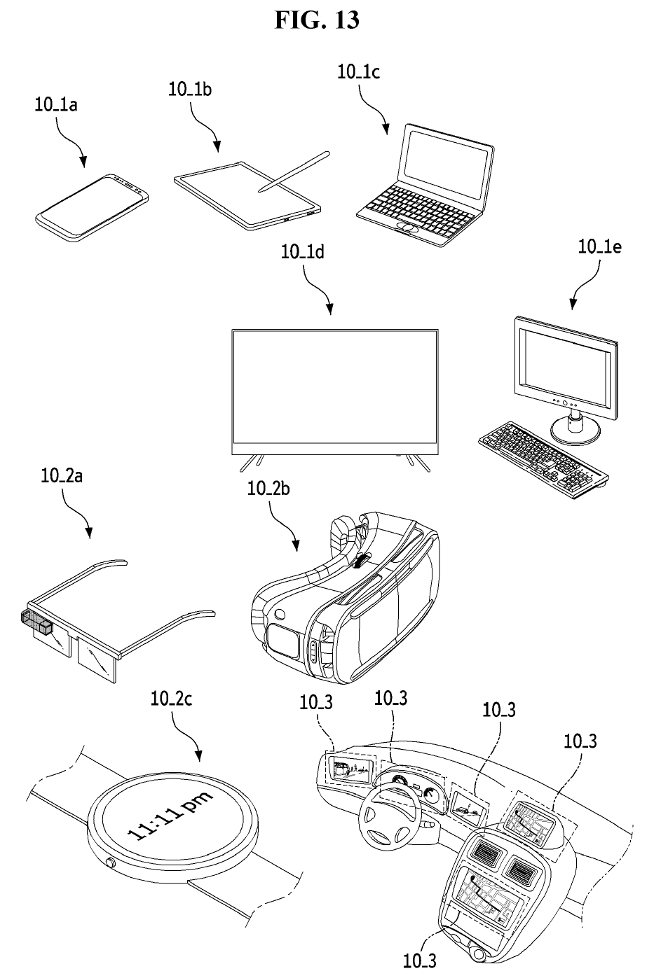

FIG. 13 illustrates schematic diagrams of electronic devices according to various embodiments.

Referring to FIG. 13, various electronic devices to which the display devices according to the embodiments are applied may include image display electronic devices such as a smartphone 10_1a, a tablet PC 10_1b, a laptop 10_1c, a TV 10_1d, and a desktop monitor 10_1e, wearable electronic devices that include a display module, such as smart glasses 10_2a, a head-mounted display 10_2b, and a smart watch 10_2c, and vehicle electronic devices 10_3 that include a display module, such as a center information display (CID) arranged on the instrument panel, center fascia, or dashboard of a vehicle, and a room mirror display.

In concluding the detailed description, those skilled in the art will appreciate that many variations and modifications can be made to the disclosed embodiments without substantially departing from the principles of the present invention. Therefore, the disclosed embodiments of the invention are used in a generic and descriptive sense only and not for purposes of limitation.

What is claimed is:

1. An optical device comprising:
a substrate;
a first electrode and a second electrode on the substrate and spaced apart from each other;
a first refractive layer on the substrate and including a first material having a first refractive index;
a second refractive layer on the first refractive layer and including a second material having a second refractive index that is lower than the first refractive index;
a third refractive layer on the second refractive layer and including the first material; and
a fourth refractive layer on the third refractive layer and including the second material,
wherein the first refractive index of the first material is configured to change in response to an electric field generated by voltages applied to the first electrode and the second electrode.

2. The optical device of claim 1, wherein a thickness of the third refractive layer is equal to a thickness of the first refractive layer.

3. The optical device of claim 2, wherein a thickness of the fourth refractive layer is equal to a thickness of the second refractive layer.

4. The optical device of claim 1, wherein a thickness of the second refractive layer is greater than a thickness of the first refractive layer.

5. The optical device of claim 1, wherein
the first electrode is between the substrate and the first refractive layer, and
the second electrode is on the fourth refractive layer.

6. The optical device of claim 1, wherein
the first electrode is on one side of the substrate and contacts the first through fourth refractive layers, and
the second electrode is on the other side of the substrate and contacts the first through fourth refractive layers.

7. The optical device of claim 1, wherein a difference between the first and second refractive indices is equal to or greater than 0.5 and equal to or less than 1.5.

8. The optical device of claim 1, wherein a difference between a maximum value and a minimum value of the first refractive index is equal to or greater than 0.01 and equal to or less than 0.03.

9. A display device comprising:
a light source; and
an optical device on one side of the light source,
wherein the optical device includes:
a substrate;
a first electrode and a second electrode on the substrate and spaced apart from each other;
a first refractive layer on the substrate and including a first material having a first refractive index;
a second refractive layer on the first refractive layer and including a second material having a second refractive index that is lower than the first refractive index;
a third refractive layer on the second refractive layer and including the first material; and
a fourth refractive layer on the third refractive layer and including the second material, and
the first refractive index of the first material is configured to change in response to an electric field generated by voltages applied to the first electrode and the second electrode.

10. The display device of claim 9, wherein the light source is configured to emit light in a predetermined wavelength band.

11. The display device of claim 9, further comprising:
an optical device driving unit configured to apply a first driving voltage and a second driving voltage to the first electrode and the second electrode, respectively.

12. The display device of claim 9, wherein the optical device is configured to reflect light emitted from the light source and to modulate an amplitude of the light.

13. The display device of claim 12, wherein the optical device is configured to reflect light emitted from the light source as the electric field increases.

14. The display device of claim 12, wherein the optical device is configured to reflect light emitted from the light source as the electric field decreases.

15. The display device of claim 9, wherein the optical device is configured to transmit light emitted from the light source and to modulate an amplitude of the light.

16. The display device of claim 15, wherein the optical device is configured to transmit light emitted from the light source as the electric field increases.

17. An electronic device comprising:
a display module configured to display an image; and
a processor configured to provide an image data signal for displaying the image to the display module,
wherein the display module includes:
a light source; and
an optical device on one side of the light source,
the optical device includes:
a substrate;
a first electrode and a second electrode on the substrate and spaced apart from each other;
a first refractive layer on the substrate and including a first material having a first refractive index;
a second refractive layer on the first refractive layer and including a second material having a second refractive index that is lower than the first refractive index;
a third refractive layer on the second refractive layer and including the first material; and
a fourth refractive layer on the third refractive layer and including the second material, and
the first refractive index of the first material is configured to change in response to an electric field generated by voltages applied to the first and second electrodes.

18. The electronic device of claim 17, wherein the display module further includes an optical device driver configured to apply first and second driving voltages to the first and second electrodes, respectively.

19. The electronic device of claim 17, wherein the processor is configured to control magnitudes and timings of the first and second driving voltages applied by the optical device driver to the first and second electrodes.

20. The electronic device of claim 17, wherein the electronic device is one of a mobile phone, a smartphone, a tablet personal computer (PC), a mobile communication terminal, an electronic notebook, an electronic book (e-book) reader, a portable multimedia player (PMP), a navigation device, an ultra mobile PC (UMPC), an Internet of Things (IoT) device, a television, a laptop computer, a monitor, a signage display, a smartwatch, a watch phone, a glasses-type display, a head-mounted display, an automotive instrument panel, an automotive center fascia, an automotive center information display (CID), or an automotive room mirror display.
